(19) United States
(12) Patent Application Publication
(10) Pub. No.: US 2009/0073758 A1
(43) Pub. Date: Mar. 19, 2009

(54) SRAM CELLS WITH ASYMMETRIC FLOATING-BODY PASS-GATE TRANSISTORS

(75) Inventors: Gregory G. Freeman, Hopewell Junction, NY (US); Qingqing Liang, Fishkill, NY (US); Mario M. Pelella, Mountain View, CA (US); Carl J. Radens, LaGrangeville, NY (US); Huicai Zhong, Wappingers Falls, NY (US); Huilong Zhu, Poughkeepsie, NY (US)

Correspondence Address: FREDERICK W. GIBB, III;Gibb Intellectual Property Law Firm, LLC, 2568-A RIVA ROAD, SUITE 304, ANNAPOLIS, MD, 21401, US

(73) Assignees: INTERNATIONAL BUSINESS MACHINES CORPORATION, Armonk, NY (US); ADVANCED MICRO DEVICES, INC., Sunnyvale, CA (US)

(21) Appl. No.: 11/857,757

(22) Filed: Sep. 19, 2007

(51) Int. Cl. G11C 11/34; H01L 21/00

(52) U.S. Cl. 365/174; 438/197; 257/E21.001

(57) ABSTRACT

The embodiments of the invention provide SRAM cells with asymmetric floating-body pass-gate transistors. More specifically, a semiconductor device includes an SRAM cell, a first pass-gate transistor, and a second pass-gate transistor. The first pass-gate transistor is connected to a first side of the SRAM cell, wherein the first pass-gate transistor comprises a first drain region and a first source region. The second pass-gate transistor is connected to a second side of the SRAM cell, wherein the second side is opposite the first side. The second pass-gate transistor comprises a second source region and a second drain region. Furthermore, the first source region and/or the second source region comprise a xenon implant. The first drain region and the second drain region each lack a xenon implant.

### BACKGROUND

1. Field of the Invention

The embodiments of the invention provide static random access memory (SRAM) cells with asymmetric floating-body pass-gate transistors.

2. Description of the Related Art

A typical static random access memory (SRAM) cell ideally includes a balanced pair of cross-coupled inverters storing a single data bit with a high at the output of one inverter and a low at the output of the other. A pair of pass-gates (also ideally, a balanced pair of FETs) selectively connect the complementary outputs of the cross-coupled inverters to a corresponding complementary pair of bit lines. A word line connected to the gates of the pass-gate FETs selects connecting the cell to the corresponding complementary pair of bit lines. During a write, the pass-gates are turned on and the bit line contents are coupled to the cross-coupled inverters, which fight the switch until the cell voltages cross and the cross-coupled inverters take over. Typically, most of the switching is done by cell NFETs, because the off-PFET does not turn on until the high-side (at the on-PFET) is pulled at least to the PFET threshold below the supply voltage, perhaps as much as ⅓ or ½ or more of the supply voltage. Similarly, during a read, each cell on the selected word line couples its contents to its corresponding bit line pair through NFET pass-gates. Since the bit line pair is typically pre-charged to some common voltage, initially, the internal (to the cell) low voltage rises until one of the bit line pairs drops sufficiently to develop a small difference signal (e.g., 50 mV). Thus, in these conventional cells, the NFETs did most, if not all of the switching and so, considerable design effort is expended tweaking cell NFET sizes to improve read and write performance.

There are three factors that limit SRAM cells soft yields. These factors include writability, readability, and stability. However, there is a trade-off among the three constraints. The prior art fails to provide a method and structure to improve these three factors simultaneously.

### SUMMARY

The embodiments of the invention provide SRAM cells with asymmetric floating-body pass-gate transistors. More specifically, a semiconductor device includes an SRAM cell, a first pass-gate transistor, and a second pass-gate transistor. The first pass-gate transistor is connected to a first side of the SRAM cell, wherein the first pass-gate transistor comprises a first drain region and a first source region. The second pass-gate transistor is connected to a second side of the SRAM cell, wherein the second side is opposite the first side. The second pass-gate transistor comprises a second source region and a second drain region.

Furthermore, the first pass-gate transistor comprises a first channel region; and, the second pass-gate transistor comprises a second channel region. The first channel region and the second channel region each comprise a xenon implant. Moreover, the first source region and/or the second source region comprise a xenon implant. The first drain region and the second drain region each lack a xenon implant. The xenon implant in the first source region and/or the second source region and the lack of the xenon implant in the first and second drain regions cause an asymmetric floating body effect in the first pass-gate transistor and/or the second pass-gate transistor.

The first pass-gate transistor is positioned between a first bit line and a first internal node of the SRAM cell, wherein the first drain region of the first pass-gate transistor is tied with the first bit line. Moreover, the first source region of the first pass-gate transistor is tied with the first internal node of the SRAM cell. The second pass-gate transistor is positioned between a second bit line and a second internal node of the SRAM cell, wherein the second drain region of the second pass-gate transistor is tied with the second bit line. Further, the second source region of the second pass-gate transistor is tied with the second internal node of the SRAM cell. Additionally, the first pass-gate transistor comprises a higher threshold-voltage and a lower drive current relative to the second pass-gate transistor.

The embodiments of the invention also provide a method of forming the semiconductor device. The method begins by simultaneously forming a first pass-gate transistor and a second pass-gate transistor adjacent an SRAM cell. This includes protecting drain regions of the first pass-gate transistor and the second pass-gate transistor with masks to avoid implantation of xenon within the drain regions.

After protecting the drain regions with the masks, the method implants xenon implants into source regions of the first pass-gate transistor and the second pass-gate transistor. If the drain regions comprise a higher voltage potential than the source regions, the xenon implants increase the threshold voltage of the first pass-gate transistor and the second pass-gate transistor. If the source regions comprise a higher voltage potential than the drain regions, the xenon implants decrease the threshold voltage of the first pass-gate transistor and the second pass-gate transistor.

After protecting the drain regions with the masks and before removing the masks, the method also implants xenon implants into channel regions of the first pass-gate transistor and the second pass-gate transistor. Subsequently, the masks are removed.

Accordingly, the embodiments of the invention improve SRAM yields via asymmetric floating-body pass-gate transistors. This provides benefits in SOI technologies with no trade-off on power and performance. Methods for forming the asymmetric pass-gate transistors are also provided with more advantage on higher voltage and higher frequency. There is no area penalty and no process adjusting penalty due to straight-forward implementation.

More specifically, an asymmetric floating-body effect is accomplished via an asymmetric xenon implant (i.e., on the source side only). This effect dynamically strengthens or weakens the pass-gates in favor of the stability and writability without degradation on readability. As more fully described below, in the read mode, the left pass-gate is weakened, which helps the stability; while in the write mode, the right pass-gate is strengthened, which helps the writability.

These and other aspects of the embodiments of the invention will be better appreciated and understood when considered in conjunction with the following description and the accompanying drawings. It should be understood, however, that the following descriptions, while indicating preferred embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a diagram illustrating a pass-gate transistor;

FIG. 2 is a diagram illustrating a semiconductor device having an SRAM cell positioned between two pass-gate transistors;

FIG. 3 is a diagram illustrating a semiconductor device in read mode;

FIG. 4 is a diagram illustrating a semiconductor device in write mode;

FIG. 5 is a diagram illustrating a pass-gate transistor of a semiconductor device;

FIG. 6 is a flow diagram illustrating a method of forming an SRAM cell with asymmetric floating-body pass-gate transistors; and

FIG. 7 is a flow diagram illustrating another method of forming an SRAM cell with asymmetric floating-body pass-gate transistors.

### DETAILED DESCRIPTION OF EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

Due to the nature of planar process of CMOS device technology, transistors are typically designed with symmetrical source and drain. To achieve higher performance in a limited biasing range (e.g., the source voltage always biased lower than the drain voltage on NFETs), some transistors implement asymmetric doping profile at source and drain sides. However, these designs sacrifice the device performance (e.g., drain-induced-barrier-lowering and short channel effect) if the biased voltages of source and drain are swapped, and are not suitable for pass-gate logic applications. The embodiments of the invention provide a NFET with the asymmetric source and drain diode leakages that induce asymmetric floating-body effect. This design exhibits asymmetric behavior (e.g., higher drive current when drain voltage is higher than source voltage, lower drive current vice versa) in pass-gate application without degrading device performance.

Accordingly, the embodiments of the invention improve SRAM yields via asymmetric floating-body pass-gate transistors. This provides benefits in SOI technologies with no trade-off on power and performance. Methods for forming the asymmetric pass-gate transistors also provide advantages for higher voltage and higher frequency devices. There is no area penalty and no process adjusting penalty due to the straight-forward implementation disclosed herein.

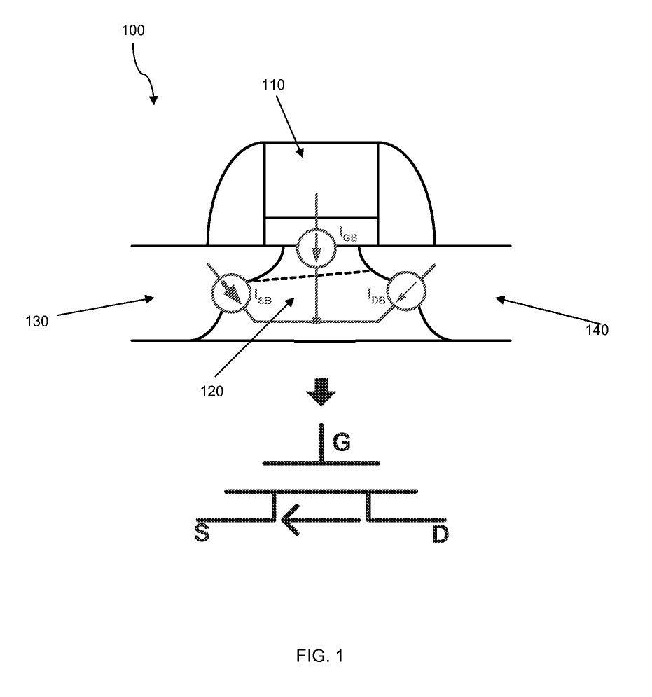

Referring to FIG. 1, a pass-gate transistor 100 is illustrated comprising a gate 110, a channel region 120, a source region 130, and a drain region 140. Many of the details of forming pass-gate transistors, gates, source regions, drain regions, etc., are well-known and are not discussed herein in detail so as to focus the reader on the salient portions of the invention. Instead, reference is made to U.S. Pat. No. 7,092,280 to Joshi for the description of such details and the same are fully incorporated herein by reference.

If diode leakage at the source region 130 (ISB) is stronger than diode leakage at the drain region 140 (IDB), then due to body potential difference caused by asymmetrical floating body effect, the asymmetrical pass-gate transistor 100 (e.g., n-type field effect transistor) exhibits lower threshold voltage as biasing Vsd=Vdd than as biasing Vds=Vdd. Vdd represents a positive applied voltage, and is also referred as the applied voltage on the bit line (BL) and word line (WL) of an SRAM. Moreover, Vsd is the voltage between the source region 130 to the drain region 140. If the voltage potential at the source region 130 is higher than the voltage potential at the drain region 140, then the Vsd is positive. Otherwise, the Vsd is negative. Vds represents the voltage between the drain region 140 to the source region 130. If the voltage potential at the drain region 140 is higher than the voltage potential at source region 130, then the Vds is positive. Otherwise, the Vds is negative.

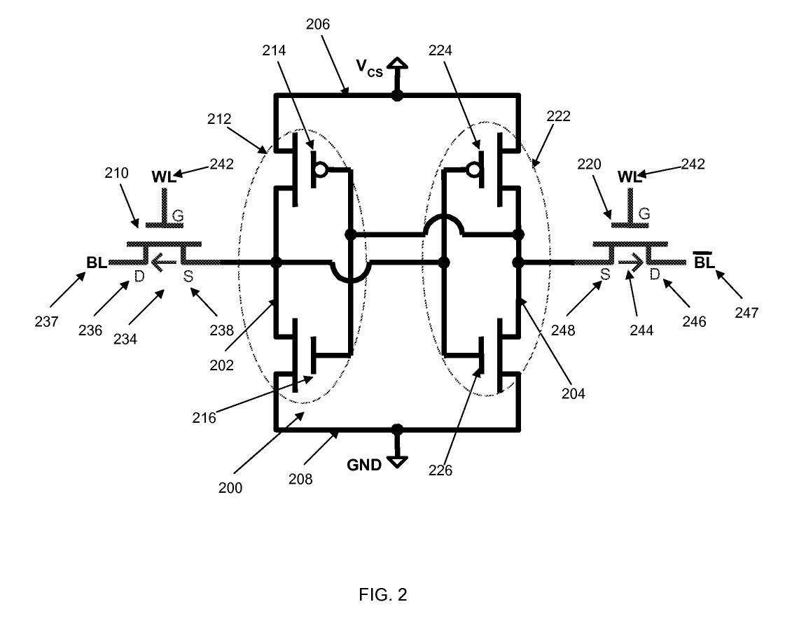

Referring now to FIG. 2, a SRAM cell 200 is shown includes two asymmetric pass-gates transistors 210 and 220 as described above. The source side 238 of pass-gate transistor 210 is connected to an internal node 202 of the SRAM cell 200; and, the source side 248 of pass-gate transistor 220 is connected to the other internal node 204 (or, complementary node of 202) of the SRAM cell 200. The pass-gates transistors 210 and 220 include channel regions 234 and 244, respectively.

Node 206 of the SRAM cell 200 is applied at a positive voltage (Vcs); and, node 208 of the SRAM cell 200 is connected to the GND. The SRAM cell 200 includes a first inverter 212, having a first transistor 214 and a second transistor 216. Additionally, the SRAM cell 200 includes a second inverter 222, having a third transistor 224 and a fourth transistor 226.

The bit line BL (node 237) is connected to the drain side 236 of pass-gate transistor 210 (also referred to herein as the “first pass-gate transistor”), and the complementary bit line BL (node 247) is connected to the drain side 246 of pass-gate transistor 220 (also referred to herein as the “second pass-gate transistor”). Further, the word line WL (node 242) is connected to the gates of both pass-gates 210 and 220.

The voltages applied to the drains (node 236 and 246) of pass-gates transistors 210 and 220, respectively, can be greater to or less than the voltage applied to the sources (node 238 and 248) of pass-gates transistors 210 and 220, respectively.

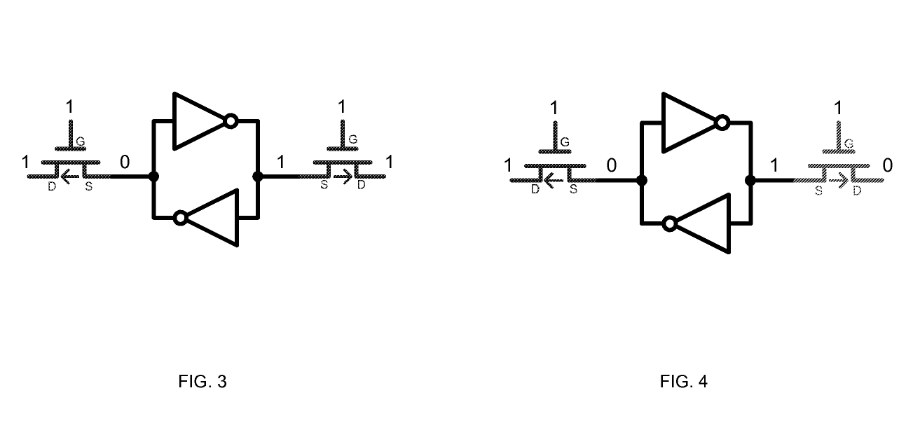

FIG. 3 illustrates the SRAM cell 200 in a read mode, when the word line WL is on (or “1”), and both the bit line and complementary bit line are pre-charged to high potential (or “1”). The internal node of cell that is at lower potential (i.e. at “0” state) is being disturbed during the read mode. Since the internal node at lower potential is connected to the source region of the first pass-gate, and the drain region of this pass-gate is connected to the bit line that is applied with higher potential (or “1”). The pass-gate has a higher threshold voltage and hence a weaker drive current. Thus, smaller disturbance is observed making the SRAM cell 200 more stable during read mode.

FIG. 4 illustrates the SRAM cell 200 in a write mode, when the word line WL is on (or “1”), and the bit line is “1” and the complementary bit line is “0”. Since the internal node at higher potential (or “1”) is connected with the source region of the second pass-gate, and the drain region of this pass-gate is connected to the complementary bit line that is applied with lower potential (or “0”). The pass-gate has a lower threshold voltage and hence a stronger drive current. Thus, stronger injection is observed making it easier to write while the SRAM cell 200 is in the write mode.

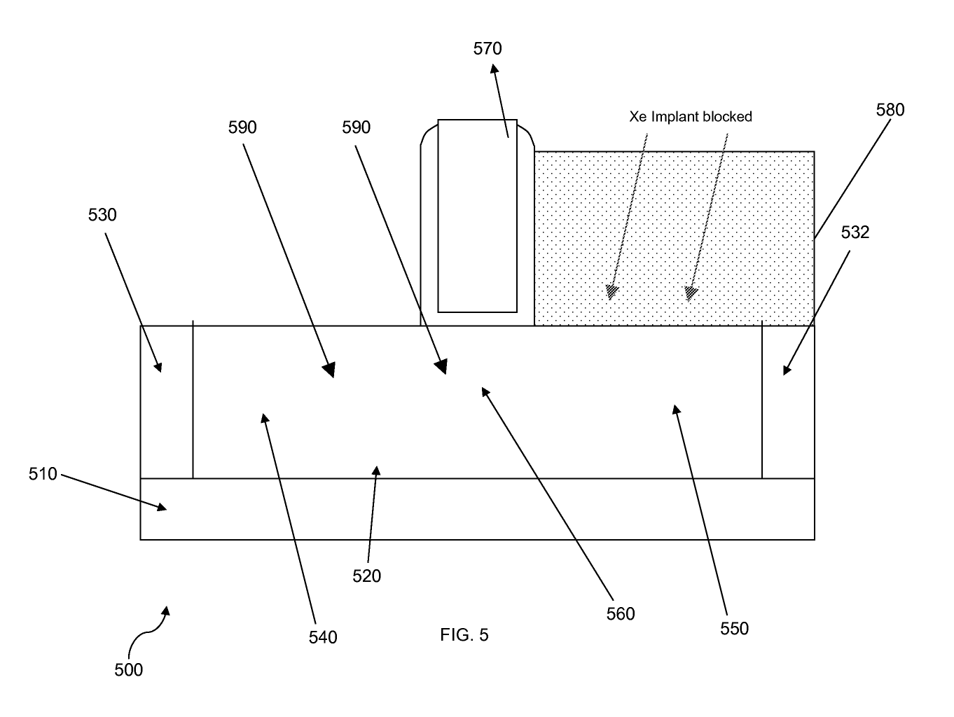

Referring now to FIG. 5, a pass-gate transistor 500 is illustrated having a silicon-on-insulator (SOI) region 520 on a buried oxide (BOX) region 510. Shallow trench isolation (STI) regions 530 and 532 are positioned on the BOX region 510, wherein the STI regions 530 and 532 are on opposite sidewalls of the SOI region 520. The STI regions 530 and 532 can be formed from oxide.

The SOI region 520 includes a source region 540 adjacent to the STI region 530 and a drain region 550 adjacent to the STI region 532. The SOI region also includes a channel region 560 between the source region 540 and the drain region 550. Further, a gate 570 is above the channel region, wherein the gate 570 can be formed from polysilicon.

A mask 580 is positioned on the drain region 550 and the STI region 532. As such, a xenon implantation process is blocked from implanting within the drain region 550; whereas the xenon implantation process is capable of implanting xenon 590 within the source region 540 and the channel region 560.

Accordingly, the embodiments of the invention provide SRAM cells with asymmetric floating-body pass-gate transistors. More specifically, a semiconductor device includes an SRAM cell, a first pass-gate transistor, and a second pass-gate transistor. The first pass-gate transistor is connected to a first side of the SRAM cell, wherein the first pass-gate transistor comprises a first drain region and a first source region. The second pass-gate transistor is connected to a second side of the SRAM cell, wherein the second side is opposite the first side. The second pass-gate transistor comprises a second source region and a second drain region.

Furthermore, the first pass-gate transistor comprises a first channel region; and, the second pass-gate transistor comprises a second channel region. The first channel region and the second channel region each comprise a xenon implant. Moreover, the first source region and/or the second source region comprise a xenon implant. The first drain region and the second drain region each lack a xenon implant. The xenon implant in the first source region and/or the second source region and the lack of the xenon implant in the first and second drain regions cause an asymmetric floating body effect in the first pass-gate transistor and/or the second pass-gate transistor.

The first pass-gate transistor is positioned between a first bit line and a first internal node of the SRAM cell, wherein the first drain region of the first pass-gate transistor is tied with the first bit line. Moreover, the first source region of the first pass-gate transistor is tied with the first internal node of the SRAM cell. The second pass-gate transistor is positioned between a second bit line and a second internal node of the SRAM cell, wherein the second drain region of the second pass-gate transistor is tied with the second bit line. Further, the second source region of the second pass-gate transistor is tied with the second internal node of the SRAM cell. Additionally, the first pass-gate transistor comprises a higher threshold-voltage and a lower drive current with respect to the second pass-gate transistor.

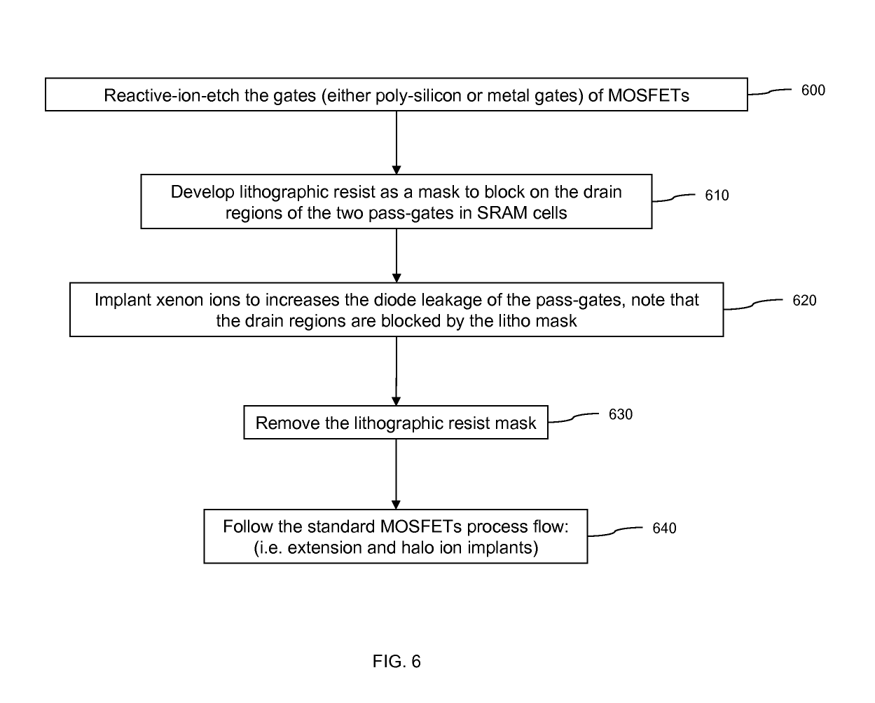

FIG. 6 is a flow diagram illustrating a method of forming an SRAM cell with asymmetric floating-body pass-gate transistors. The method begins in item 600 by reactive-ion-etch (RIE) the gates (either poly-silicon or metal gates) of MOSFETs. Then, in item 610, a lithographic resist mask is developed to block the drain regions of the pass-gates of SRAM cells. After that, in item 620, xenon ions are implanted through the wafer to increase the diode leakage, the drain sides of the pass-gates are not affected since there is a lithographic mask on the top. After xenon implantation, the lithographic resist mask is removed, in item 630, and followed by the standard flow (i.e., extension and halo implantation) in item 640.

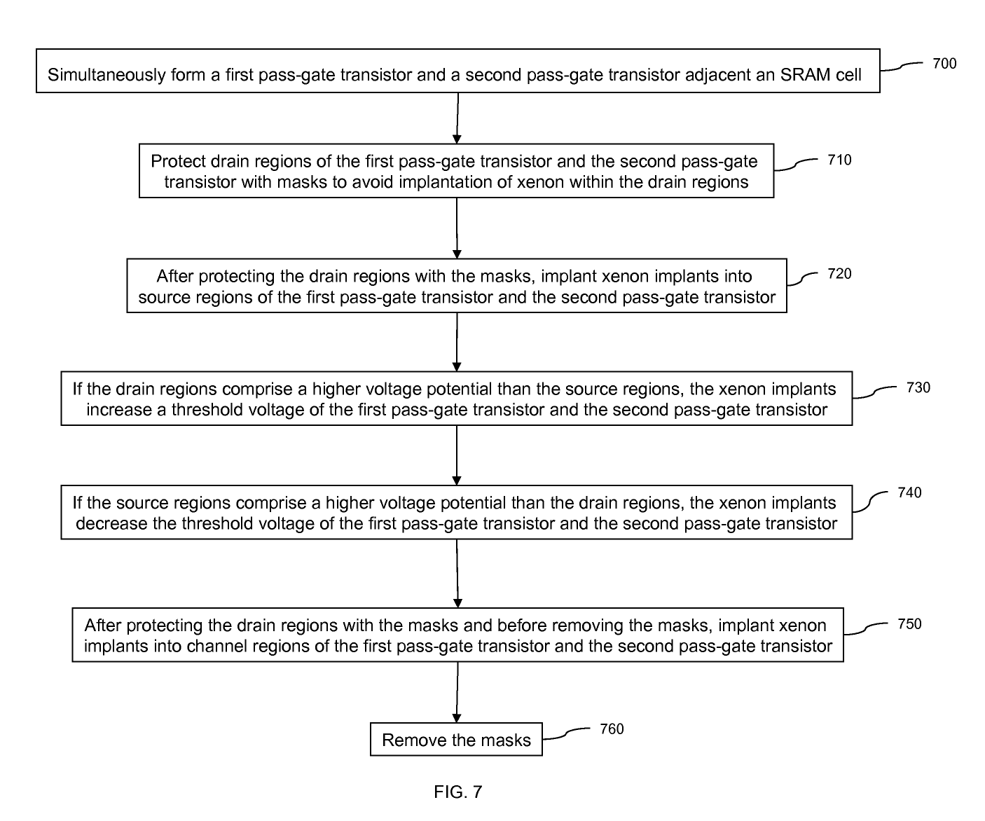

FIG. 7 is a flow diagram illustrating another method of forming an SRAM cell with asymmetric floating-body pass-gate transistors. The method begins in item 700 by simultaneously forming a first pass-gate transistor and a second pass-gate transistor adjacent an SRAM cell. This includes, in item 710, protecting drain regions of the first pass-gate transistor and the second pass-gate transistor with masks to avoid implantation of xenon within the drain regions.

After protecting the drain regions with the masks, in item 720, the method implants xenon implants into source regions of the first pass-gate transistor and the second pass-gate transistor. If the drain regions comprise a higher voltage potential than the source regions, the xenon implants increase a threshold voltage of the first pass-gate transistor and the second pass-gate transistor (item 730). If the source regions comprise a higher voltage potential than the drain regions, the xenon implants decrease the threshold voltage of the first pass-gate transistor and the second pass-gate transistor (item 740).

After protecting the drain regions with the masks and before removing the masks, in item 750, the method also implants xenon implants into channel regions of the first pass-gate transistor and the second pass-gate transistor. Subsequently, in item 760, the masks are removed.

Accordingly, the embodiments of the invention improve SRAM yields via asymmetric floating-body pass-gate transistors. This provides benefits in SOI technologies with no trade-off on power and performance. Methods for forming the asymmetric pass-gate transistors also provide advantages for higher voltage and higher frequency devices. There is no area penalty and no process adjusting penalty due to the straight-forward implementation disclosed herein.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of preferred embodiments, those skilled in the art will recognize that the embodiments of the invention can be practiced with modification within the spirit and scope of the appended claims.

What is claimed is:

1. A semiconductor device, comprising:
a static random access memory (SRAM) cell;
a first pass-gate transistor connected to a first side of said SRAM cell, wherein said first pass-gate transistor comprises a first drain region and a first source region; and
a second pass-gate transistor connected to a second side of said SRAM cell, wherein said second side is opposite said first side, wherein said second pass-gate transistor comprises a second source region and a second drain region,
wherein at least one of said first source region and said second source region comprises a xenon implant, and
wherein said first drain region and said second drain region each lack a xenon implant.

2. The semiconductor device according to claim 1, wherein said first pass-gate transistor comprise a first channel region, wherein said second pass-gate transistor comprises a second channel region, and wherein said first channel region and said second channel region each comprise a xenon implant.

3. The semiconductor device according to claim 1, wherein said first pass-gate transistor is positioned between a first bit line and a first internal node of said SRAM cell.

4. The semiconductor device according to claim 3, wherein said first drain region of said first pass-gate transistor is tied with said first bit line, and wherein said first source region of said first pass-gate transistor is tied with said first internal node of said SRAM cell.

5. The semiconductor device according to claim 1, wherein said second pass-gate transistor is positioned between a second bit line and a second internal node of said SRAM cell.

6. The semiconductor device according to claim 5, wherein said second drain region of said second pass-gate transistor is tied with said second bit line, and wherein said second source region of said second pass-gate transistor is tied with said second internal node of said SRAM cell.

7. The semiconductor device according to claim 1, wherein said first pass-gate transistor comprises a higher threshold-voltage and a lower drive current with respect to said second pass-gate transistor.

8. The semiconductor device according to claim 1, wherein said xenon implant in said at least one of said first source region and said second source region and said lack of said xenon implant in said first drain region and said second drain region causes an asymmetric floating body effect in at least one of said first pass-gate transistor and said second pass-gate transistor.

9. A semiconductor device, comprising:
a static random access memory (SRAM) cell;
a first pass-gate transistor connected to a first side of said SRAM cell, wherein said first pass-gate transistor comprises a first drain region and a first source region; and
a second pass-gate transistor connected to a second side of said SRAM cell, wherein said second side is opposite said first side, wherein said second pass-gate transistor comprises a second source region and a second drain region,
wherein said first pass-gate transistor comprise a first channel region, wherein said second pass-gate transistor comprises a second channel region, and wherein said first channel region and said second channel region each comprise a xenon implant,
wherein at least one of said first source region and said second source region comprises a xenon implant, and
wherein said first drain region and said second drain region each lack a xenon implant.

10. The semiconductor device according to claim 9, wherein said first pass-gate transistor is positioned between a first bit line and a first internal node of said SRAM cell.

11. The semiconductor device according to claim 10, wherein said first drain region of said first pass-gate transistor is tied with said first bit line, and wherein said first source region of said first pass-gate transistor is tied with said first internal node of said SRAM cell.

12. The semiconductor device according to claim 9, wherein said second pass-gate transistor is positioned between a second bit line and a second internal node of said SRAM cell.

13. The semiconductor device according to claim 12, wherein said second drain region of said second pass-gate transistor is tied with said second bit line, and wherein said second source region of said second pass-gate transistor is tied with said second internal node of said SRAM cell.

14. The semiconductor device according to claim 9, wherein said first pass-gate transistor comprises a higher threshold-voltage and a lower drive current with respect to said second pass-gate transistor.

15. The semiconductor device according to claim 9, wherein said xenon implant in said at least one of said first source region and said second source region and said lack of said xenon implant in said first drain region and said second drain region causes an asymmetric floating body effect in at least one of said first pass-gate transistor and said second pass-gate transistor.

16. A method of simultaneously forming a first pass-gate transistor and a second pass-gate transistor adjacent a static random access memory (SRAM) cell, said method comprising:
forming source regions and drain regions of said first pass-gate transistor and source regions and drain regions of said second pass-gate transistor;
protecting drain regions of said first pass-gate transistor and drain regions of said second pass-gate transistor with masks;
after said protecting of said drain regions with said masks, implanting xenon implants into source regions of said first pass-gate transistor and said second pass-gate transistor, wherein, if said drain regions comprise a higher voltage potential than said source regions, said xenon implants increase a threshold voltage of said first pass-gate transistor and said second pass-gate transistor, and wherein, if said source regions comprise a higher voltage potential than said drain regions, said xenon implants decrease said threshold voltage of said first pass-gate transistor and said second pass-gate transistor; and
removing said masks.

17. The method according to claim 16, further comprising, after said protecting of said drain regions with said masks and before said removing of said masks, implanting xenon implants into channel regions of said first pass-gate transistor and said second pass-gate transistor.

18. The method according to claim 16, wherein said protecting of said drain regions comprises avoiding implantation of xenon within said drain regions.

19. A method of simultaneously forming a first pass-gate transistor and a second pass-gate transistor adjacent a static random access memory (SRAM) cell, said method comprising:
forming source regions and drain regions of said first pass-gate transistor and source regions and drain regions of said second pass-gate transistor;
protecting drain regions of said first pass-gate transistor and drain regions of said second pass-gate transistor with masks, wherein said protecting of said drain regions of said first pass-gate transistor and said drain regions of said second pass-gate transistor comprises avoiding implantation of xenon within said drain regions of said first pass-gate transistor and said drain regions of said second pass-gate transistor;
after said protecting of said drain regions with said masks, implanting xenon implants into source regions of said first pass-gate transistor and said second pass-gate transistor, wherein, if said drain regions comprise a higher voltage potential than said source regions, said xenon implants increase a threshold voltage of said first pass-gate transistor and said second pass-gate transistor, and wherein, if said source regions comprise a higher voltage potential than said drain regions, said xenon implants decrease said threshold voltage of said first pass-gate transistor and said second pass-gate transistor; and
removing said masks.

20. The method according to claim 19, further comprising, after said protecting of said drain regions with said masks and before said removing of said masks, implanting xenon implants into channel regions of said first pass-gate transistor and said second pass-gate transistor.
